(19) United States
(12) Patent Application Publication
(10) Pub. No.: US 2009/0101885 A1
(43) Pub. Date: Apr. 23, 2009

(54) Method of producing phase change memory device

(75) Inventors: Akiyoshi Seko, Tokyo (JP); Natsuki Sato, Tokyo (JP); Isamu Asano, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/285,686

(22) Filed: Oct. 10, 2008

(30) Foreign Application Priority Data
Oct. 18, 2007 (JP) 2007-271428

(51) Int. Cl. H01L 29/06; H01L 21/76

(52) U.S. Cl. 257/5; 438/429; 257/E21.54; 257/E29.005

(57) ABSTRACT

An area where a lower electrode is in contact with a variable resistance material needs to be reduced in order to lower the power consumption of a variable resistance memory device. The present invention provides a method of producing a variable resistance memory element whereby the lower electrode can be more finely formed. The method of producing a semiconductor device according to the present invention includes forming a small opening by utilizing cubical expansion due to the oxidation of silicon. Thereby forming the lower electrode smaller than that can be formed by lithography techniques.

### BACKGROUND OF THE INVENTION

1. Field of the Invention

The present invention relates to an electrically rewritable non-volatile memory device and a method of producing the same.

2. Description of the Related Art

In a recent highly-sophisticated information society, there has been a demand for further improvement in performance of a solid-state memory device formed by using a semiconductor integrated circuit technology. In particular, as a computational capacity of a micro processing unit (MPU) is improved, memory capacities of a computer and an electronic apparatus have been increased. Unlike a magnetic and a magneto-optical storage device such as a hard disk and a laser disk, the solid-state memory device does not have a physically driving portion therein. The solid-state memory device, therefore, has a high mechanical strength and can be highly integrated based on the semiconductor manufacturing technology. For this reason, the solid-state memory device has been used not only as a temporary storage device (cache) and a main storage device (main memory) for a computer and a server, but also as an external storage device (storage memory) for a large number of mobile apparatus and household electrical appliances and has built up the market on the order of several tens of billions of dollars at present.

Such solid-state memory devices are classified into three types according to their principle of operation: a static random access memory (SRAM), a dynamic random access memory (DRAM) and an electrically erasable and programmable read only memory (EEPROM) which is represented by a flush memory device. The SRAM is the fastest among the above memory devices; however, it cannot hold information while power supply is turned off, and requires a large number of transistors for one bit, which is not suitable for providing a large capacity. For this reason, the SRAM is mainly used as a cache in an MPU. The DRAM requires a refresh operation and operates slower than the SRAM; however, it can easily be integrated at a lower unit cost for one bit. Therefore, the DRAM is mainly used for a maim memory of a computer and a household electrical appliance.

On the other hand, the EEPROM is a non-volatile memory device capable of holding information even while power supply is turned off. The EEPROM is slower in writing and erasing information than the above devices and requires a relatively large electric power, and therefore, it is mainly used for a storage memory.

As the market for mobile communication equipment has rapidly grown in recent years, there has been a demand for the development of a DRAM-compatible solid-state memory device which is faster and capable of operating at a lower power consumption, and even a non-volatile solid-state memory device having features of both the DRAM and EEPROM. For such a next-generation solid-state memory device, an attempt has been made to develop a resistive random access memory (RRAM) using a variable resistor and a ferroelectric RAM (FeRAM) using a ferroelectric substance. In addition, one of promising candidates for a non-volatile memory device which is faster and capable of operating at a lower power consumption is a phase change random access memory (PRAM) using a phase change material. The phase change random access memory writes information at a speed as high as about 50 ns and has the advantage that the memory can be easily integrated because of its simple configuration.

The phase change memory device is a non-volatile memory device having a structure in which a phase change material is sandwiched between two electrodes. The memory device is selectively operated by an active element connected in series in a circuit. The active element includes, for example, a metal-oxide-semiconductor (MOS) transistor, a junction diode, a bipolar transistor and a Schottky barrier diode. FIG. 21 is a schematic cross section of a general vertical phase change memory device. FIG. 22 is a schematic cross section of a vertical phase change memory cell in which a general select MOS transistor is arranged. The vertical phase change memory device has such a structure that two electrodes in contact with the phase change material are arranged perpendicularly (vertically) with respect to the material. FIG. 23 is a circuit configuration of one cell corresponding to FIG. 22. A memory cell array is formed by cells arranged in a lattice configuration and each cell is made up of the combination of the phase change memory device and an active select element (or MOS transistor in case of FIG. 23). This structure is characterized in that the cell can be easily and highly integrated and the cell integration techniques for the DRAM can be used because the cell is similar in configuration to the DRAM. As the case may be, the configuration of memory cell peripheral circuits and the memory cell can be further devised to form a memory cell without an active select element.

Storage and erasure of data in the phase change memory device are performed by using thermal energy to cause a transition between two or more solid phases, such as (poly) crystal state and amorphous state in a phase change material. The transition between the crystal state and the amorphous state is identified as change in a resistance value from a circuit connection through the electrodes. To apply the thermal energy to the phase change material, an electric pulse (voltage or current pulse) is applied between the electrodes to heat the phase change material itself from Joule heating. At this point, for example, an electric pulse of a large current is applied to a phase change material in a crystal state for a short time to heat the phase change material to a high temperature near a melting point and then quench it, thereby turning the phase change material into an amorphous state (this state is called “resetting state”). This operation is generally referred to as resetting operation. On the other hand, in the resetting state, an electric pulse of a current smaller than in the resetting operation is applied to the phase change material for a relatively long time to heat the phase change material to the temperature of crystallization, thereby turning the phase change material into a crystal state (this state is called “setting state”). This operation is referred to as setting operation in contrast with the resetting operation.

Since the phase change memory device is activated by the active select element, information needs to be rewritten within the driving current capacity of the active select element. However, in a phase change memory device produced in the currently latest lithography technology, it is difficult to keep a current value required for the resetting operation within the driving current capacity of the active select element, while maintaining the cell integration level as much as other memories such as the DRAM.

It is effective to reduce (scale) the phase change area of the phase change material for enabling the vertical phase change memory device to switch at a low electric power (current). For example, it is desirable to fully cover a lower (or an upper) electrode with a phase-change area or cause all paths of current flowing into the phase change material to always pass the phase change area, in order to identify the transition of states of the phase change material as change in a resistance value when the resetting operation is performed from the setting state. The phase change area refers to an area where a phase change actually occurs. All the volume of the formed phase change material does not always need to be the phase change area.

In the phase change memory device illustrated in FIG. 21, the phase change area in the phase change material is formed in the vicinity of an interface between the phase change material and a lower electrode where the highest current density appears at the time of writing information. In other words, heat is generated around the portion where the phase change material is in contact with the lower electrode and that portion mainly exhibits phase change. For this reason, reducing the contact cross section of the lower electrode in contact with the phase change material helps to reduce the phase change area and power consumption at the time of rewriting information. When the self-joule heating occurs in the phase change material, the most of the heat will be dissipated in the electrode. From these standpoints, it is effective to reduce the contact cross section of the electrode in contact with the phase change material and the cross section of the electrode itself in terms of suppressing heat radiation from the phase change material and efficiently causing the phase change.

However, in a typical semiconductor manufacturing process, the dimension of the electrode connected to the phase change material is determined by the minimum processing dimension in a lithography processing, so that it is difficult to reduce the dimension as small as the process trend or lower. The minimum processing dimension is the minimum formable processing linewidth dimension or the minimum formable processing space dimension which is determined by a manufacturing process, such as the resolution capability in photolithography and the processing capability in etching.

As described in Patent Document 1 and non-Patent Document 1, there has been presently proposed a technique in which a thin film electrode material is deposited on a trench structure (U shaped trench) and a protective insulating material and an insulating material are deposited thereon and planarization is performed, thereby forming a fine electrode independently of lithography techniques. FIGS. 24 and 25 are schematic diagrams illustrating a vertical cross section of an electrode in its forming step. As illustrated in FIG. 24, a lower electrode material and a protective insulating material are deposited on a trench structure and an insulating material is further deposited thereon by an SOG method. As illustrated in FIG. 25, planarization is performed using a CMP method, thereby forming a phase change memory device illustrated in FIG. 1. The method is capable of forming a lower electrode with a micro-cross section using only a relatively easy processing.

The necessity of forming such a fine electrode is not limited to the phase change memory device. Patent Document 2 describes that the physical property change area of a variable resistor needs to be reduced in an RRAM.

The RRAM is a non-volatile memory element making use of the fact that a resistance change material exhibits resistance switching by applying a voltage pulse, and refers to all materials exhibiting the resistance switching based on a principle other than a resistance change caused by phase change like the phase change memory element.

[Patent Document 1] US2003/0193063 A1

[Patent Document 2] Japanese Patent Laid-Open No. 2007-180474

[Non-Patent Document 1] F. Bedeschi et al. IEEE J. Solid-State Circuit 40 (2005) 1557.

As described above, reduction in power consumption (particularly, current consumption) at the time of rewriting information in the phase change memory device is an essential issue to be resolved for an actual mass production. In general, it has been known that the reduction of a contact area between the phase change material and the electrode reduces not only heat radiation from the electrode, but also power consumption (current) because the resistance switching can be achieved only in a small phase change area. However, in the manufacturing method of the vertical phase change memory device mainly based on a conventional lithography processing technique, the cross section of the electrode is determined by the minimum processing dimension in the lithography processing technique at the time of forming the electrode perpendicularly with respect to the phase change material (or to a substrate), so the improvement of performances of a semiconductor manufacturing apparatus is essential to reduce power consumption (current).

At present, as a method of solving the above issue, the Patent Document 1 and the non-Patent Document 1 have proposed a method in which an ultrathin electrode material is deposited on a trench structure. FIG. 1 is a schematic cross section of a vertical phase change memory device produced by the proposed method. The use of the trench structure allows a contact area to be reduced to approximately a fifth of an area in the related art. However, in the method, as illustrated in the three dimensional schematic diagram in the vicinity of the electrode in FIG. 2, while electrode width “d” in the X direction in the figure can be reduced to approximately 10 nm, electrode width “w” can be reduced only to the minimum processing dimension in the lithography processing because a lithography technique is used for processing in the Y direction in the figure.

### SUMMARY OF THE INVENTION

A method of producing a semiconductor device according to the present invention is characterized in that a small opening is formed by utilizing cubical expansion due to the oxidation of silicon.

According to the present invention, a lower electrode finer than the one fabricated using only the lithography processing technique in semiconductor manufacturing can be formed. Therefore, a contact area between the lower electrode and a variable resistance material such as (for example) a phase change material can be reduced further than the one in the related art. This enables the reduction of power consumption (in particular, current consumption) required at the time of rewriting information in a variable resistance memory device.

### BRIEF DESCRIPTION OF THE DRAWINGS

FIG. 1 is a schematic cross section of a phase change memory element in which an electrode is formed using a trench structure;

FIG. 2 is a three dimensional schematic diagram around an electrode of a phase change memory element in which the electrode is formed using the trench structure;

FIG. 3 is a partial cross section of a phase change memory element with a fine lower electrode;

FIG. 4 is a top view (a) and a partial cross section (b) illustrating a state in which an insulating layer is patterned, then a contact plug material is deposited and a planarization process is performed;

FIG. 5 is a top view (a) and a partial cross-section (b) illustrating a state in which the contact plug is selectively etched, following FIG. 4;

FIG. 6 is a top view (a) and a partial cross section (b) illustrating a state in which polysilicon is so deposited as to have isotropic step coverage, following FIG. 5;

FIG. 7 is a top view (a) and a partial cross section (b) illustrating a state in which the polysilicon is subjected to an anisotropic etching to form a side wall of silicon on the contact plug, following FIG. 6;

FIG. 8 is a top view (a) and a partial cross section (b) illustrating a state in which the polysilicon at the side wall portion is oxidized to reduce the diameter of an opening, following FIG. 7;

FIG. 9 is a top view (a) and a partial cross section (b) illustrating a state in which a lower electrode material is deposited, following FIG. 8;

FIG. 10 is a top view (a) and a partial cross section (b) illustrating a state in which the lower electrode material and a material of the insulating layer are polished by the CMP method or the etch-back method to be planarized, following FIG. 9;

FIG. 11 is a partial cross section illustrating a state in which a phase change layer and an upper electrode are formed to form a vertical phase change memory device, following FIG. 10;

FIG. 12 is a top view (a) and a partial cross section (b) illustrating a state in which the contact plug material is deposited and the surface thereof is planarized;

FIG. 13 is a top view (a) and a partial cross section (b) illustrating a state in which the contact plug is selectively etched, following FIG. 12;

FIG. 14 is a top view (a) and a partial cross section (b) illustrating a state in which polysilicon (Si) is so deposited as to have isotropic step coverage, following FIG. 13;

FIG. 15 is a top view (a) and a partial cross section (b) illustrating a state in which the polysilicon is selectively oxidized, following FIG. 14;

FIG. 16 is a top view (a) and a partial cross section (b) illustrating a state in which silicon dioxide is subjected to an anisotropic etching to remove the silicon dioxide at the upper center of the contact plug, forming a side wall of silicon dioxide at the opening, following FIG. 15;

FIG. 17 is a top view (a) and a partial cross section (b) illustrating a state in which the lower electrode material is deposited, following FIG. 16;

FIG. 18 is a top view (a) and a partial cross section (b) illustrating a state in which the surface is polished and planarized to form the lower electrode with a fine cross section, following FIG. 17;

FIG. 19 is a partial cross section illustrating a state in which the phase change layer and the upper electrode are formed to complete a vertical phase change memory device, following FIG. 18;

FIG. 20 is a partial cross section illustrating a state in which the lower electrode is selectively etched and then the phase change layer and the upper electrode are formed to complete the phase change memory device, following FIG. 18;

FIG. 21 is a schematic cross section of a general vertical phase change memory device;

FIG. 22 is a schematic cross section of a vertical phase change memory device in which a general select MOS transistor is arranged;

FIG. 23 is a circuit configuration of one cell corresponding to FIG. 21;

FIG. 24 is a partial cross section illustrating a state in which a lower electrode, a protective insulating layer and an insulating layer are deposited in a trench structure; and

FIG. 25 is a partial cross section illustrating a state in which the surface is etched to expose the lower electrode, following FIG. 23.

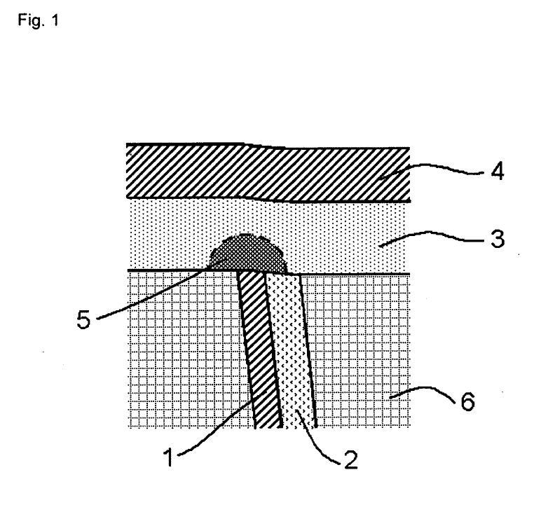

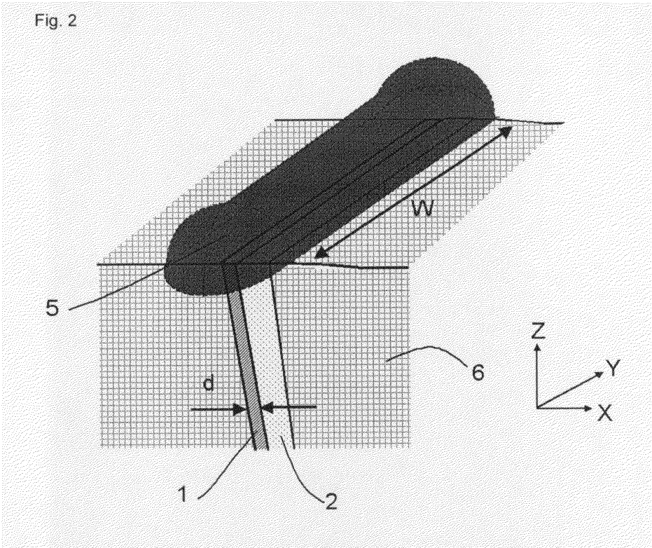

### DETAILED DESCRIPTION OF THE PREFERRED EMBODIMENTS

In a lithography processing technique, a photosensitive resin film is formed on a substrate on which a circuit pattern is developed by means of light or an electron beam. With miniaturization of semiconductor devices in recent years, light used in the lithography shifts to a short-wavelength light and is recently reaching an extreme ultraviolet ray region which is the limit of short wavelength. With use of ArF excimer laser, the current minimum dimension which can be processed using light of a wavelength in the extreme ultraviolet ray region is at approximately 70 nm.

As described above, a contact area between a lower electrode and a variable resistance material (for example, a phase change material) needs to be reduced in order to lower the power consumption of a variable resistance memory device typified by the phase change memory device, and it is required to more finely form the lower electrode.

The present inventors have made extensive studies and have found that the lower electrode can be more finely formed by utilizing cubical expansion due to the oxidation of silicon film formed by sputtering method or vapor deposition method.

A method of producing a semiconductor device according to the present invention includes forming a small opening by utilizing cubical expansion due to the oxidation of silicon.

Furthermore, a method of producing a semiconductor device according to the present invention, includes:

a first step of forming an insulating layer on a substrate on which an active select element or a lower wire is formed and forming a first opening connected to the lower wire or the active select element;

a second step of depositing a conductive material on the first opening and the insulating layer, and planarizing it to form a contact plug in the first opening;

a third step of forming a second opening by selectively etching a part of the contact plug on a flat surface which is formed of the contact plug and the insulating layer;

a fourth step of depositing silicon on the second opening and shaping the silicon by anisotropic etching to form a sidewall comprised of the silicon on a side wall of the second opening;

a fifth step of reducing the diameter of the second opening by selectively oxidizing the sidewall comprised of the silicon to a silicon dioxide (SiO₂);

a sixth step of depositing a material for a lower electrode in the second opening the diameter of which is reduced, and polishing and planarizing the material to form the lower electrode in the second opening; and

a seventh step of forming a variable resistance layer and an upper electrode in this order on the insulating layer including at least on the lower electrode.

Still furthermore, a method of producing a semiconductor device according to the present invention, includes:

a first step of forming an insulating layer on a substrate on which an active select element or a lower wire is formed and forming a first opening connected to the lower wire or the active select element;

a second step of depositing a conductive material on the first opening and the insulating layer, and planarizing it to form a contact plug in the first opening;

a third step of forming a second opening by selectively etching a part of the contact plug on a flat surface which is formed of the contact plug and the insulating layer;

a fourth step of depositing silicon on the second opening and oxidizing the deposited silicon to reduce the diameter of the second opening;

a fifth step of subjecting the oxidized silicon to an anisotropic etching process to such an extent that the contact plug is exposed;

a sixth step of depositing a material of a lower electrode in the opening the diameter of which is reduced, and polishing and planarizing the material to form a lower electrode; and

a seventh step of forming a variable resistance layer and an upper electrode in this order on the insulating layer including at least on the lower electrode.

According to the present invention, the dimension of horizontal cross section of the lower electrode can be made smaller than the minimum processing dimension in the lithography technology and a contact area of the lower electrode in contact with the variable resistance material can be made smaller than the one in the related art. Therefore, according to the present invention, it is possible to produce a variable resistance memory element (non-volatile) capable of operating at a low power consumption. In particular, it is possible to provide a vertical phase change memory device with a lower electrode formed in a dimension smaller than the minimum processing dimension in the lithography processing technology. The use of the phase change memory device produced according to the present production method enables power (current) consumption to be further reduced at the time of writing information as compared with that of a conventional vertical phase change memory device.

As a material for the upper and the lower electrodes, any known electrode material may be used without any specific limitation. For example, materials which can be used include titanium (Ti), tantalum (Ta), molybdenum (Mo), niobium (Nb), zirconium (Zr) or tungsten (W), or nitride of these metals, or a silicide compound containing these metals and nitride of these metals. Also, an alloy containing the above metals may be used. Such a compound as nitride and silicide forming the electrode material does not need to be in stoichiometric ratio. In addition, impurities such as carbon (C) and the like may be added to the electrode material.

A conductive material may be used as a material for the contact plug. The material is not particularly limited, but tungsten (W) and molybdenum (Mo) are preferable because a selective oxidation technique (refer to Japanese Patent Laid-Open No. 10-335652) can be applied thereto. In addition, a material used in the above electrode material, or copper (Cu) and aluminum (Al) used as a general wiring material or an alloy thereof may be used. In this case, however, a plug material is oxidized at the same time as the time of oxidation of silicon. Therefore, the oxide of the plug material needs to be removed after oxidation process.

As a material for the insulating layer, any known insulating film may be used without any specific limitation. For example, silicon oxide or silicon nitride may be used.

Materials for the variable resistance layer (hereinafter referred to as a “variable resistance material”) may be any material whose electric resistance can be varied by voltage applied thereto and which is available as an information recording medium capable of storing and erasing data, and include, for example, resistance change materials mainly using transition metal oxide such as titanium oxide (TiO₂), nickel oxide (NiO) and copper oxide (CuO) or transition metal oxide comprised of elements more than that and a phase change material such as a chalcogenide material. In the present invention, the variable resistance material is not limited to the phase change material. The resistance change materials, instead of the phase change materials, can provide the advantage of the fine electrode application. A fine electrode formed to reduce power (current) consumption may reduce the physical property change area of the variable resistance material where the resistance changes.

The phase change material may be any material which has two or more phase states and has different electric resistances depending on a phase state. Although not particularly limited, it is preferable to use a chalcogenide material. A chalcogen element is a type of atoms belonging to VI group of the periodic table and refers to sulfur (S), selenium (Se) and tellurium (Te). In general, a chalcogenide material refers to a compound containing one or more chalcogen elements and one or more elements of germanium (Ge), tin (Sn) and antimony (Sb). In this case, a material with added elements such as nitrogen (N), oxygen (O), copper (Cu) and aluminum (Al) may be used. For example, the compounds include the elements of binary system such as GaSb, InSb, InSe, Sb₂Te₃ and GeTe, the elements of ternary system such as Ge₂Sb₂Te₅, InSbTe, GaSeTe, SnSb₂Te₄ and InSbGe and the elements of quaternary system such as AgInSbTe, (GeSn)SbTe, GeSb(SeTe) and Te₈₁Ge₁₅Sb₂S₂.

The insulating materials include, for example, silicon dioxide (SiO₂), silicon nitride (SiN) and oxynitride silicon (SiON).

A method of reducing the diameter of the opening by forming a side wall may be accomplished by utilizing cubical expansion due to the oxidation of silicon. For example, silicon can be deposited on the main surface of the substrate including the second opening and subjected to the anisotropic etching to form a side wall formed of silicon on a side wall of the second opening and then the side wall can be oxidized. As other examples of the method, silicon may be deposited on the main surface of the substrate including the second opening, oxidized into silicon dioxide and subjected to the anisotropic etching.

The material for the contact plug, the material for the upper or the lower electrode, the insulating layer, the variable resistance material and the silicon may be deposited by any known depositing method without any specific limitation. For example, a physical vapor growth method using a sputter apparatus, a chemical vapor deposition (CVD) method, a sol-gel method or a spin coating method may be used.

The present invention is characterized in that the diameter of the opening is reduced by utilizing cubical expansion due to the oxidation of silicon to form the lower electrode in the reduced opening. At that point, silicon is converted to silicon dioxide and the silicon dioxide functions as an insulator.

The preferable embodiments are described below, and the variable resistance element and a method of producing the same in the present invention are described in detail. The present invention is not limited to the following embodiments.

### First Embodiment

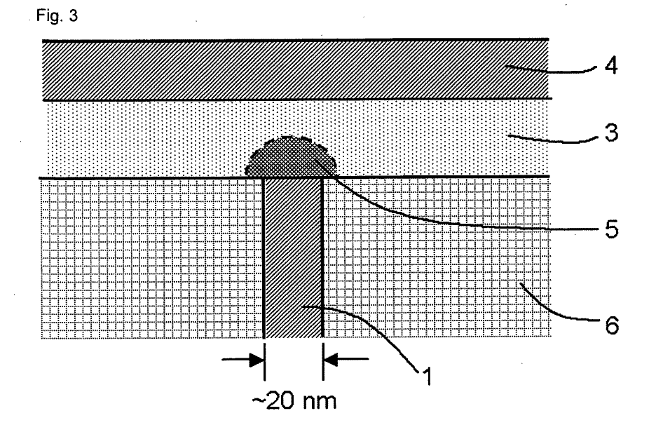

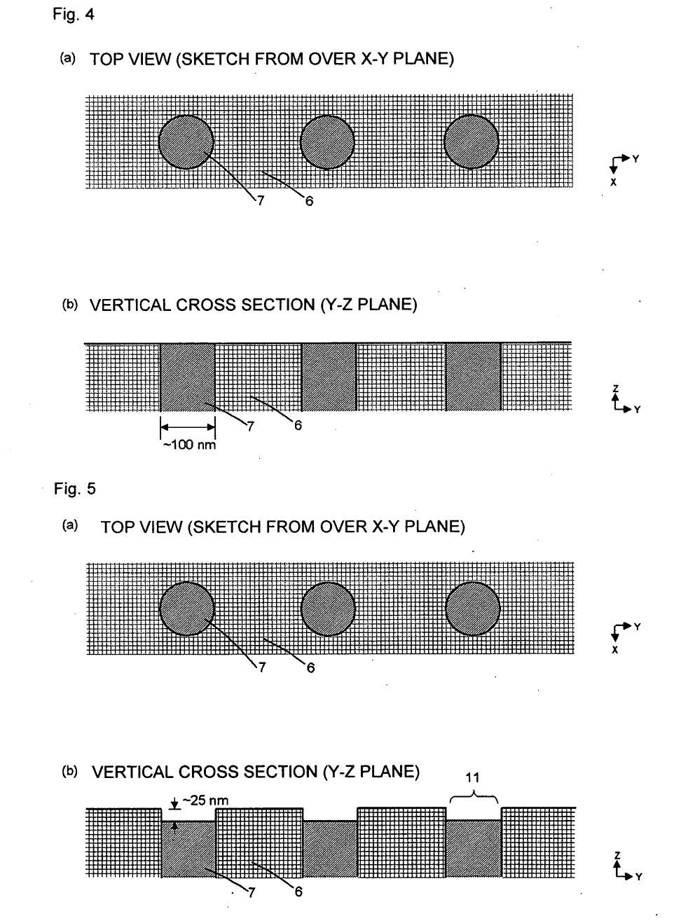

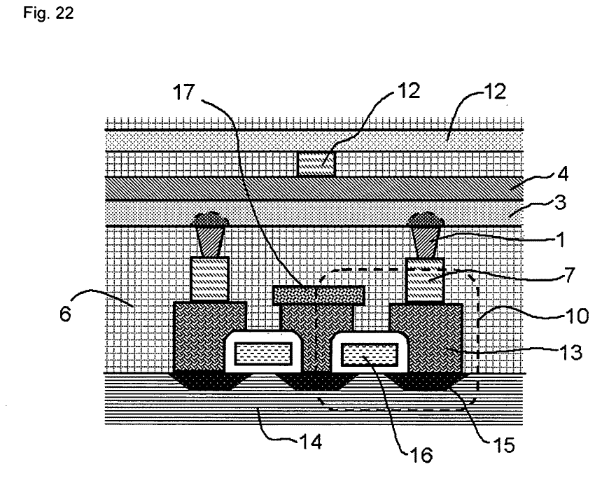

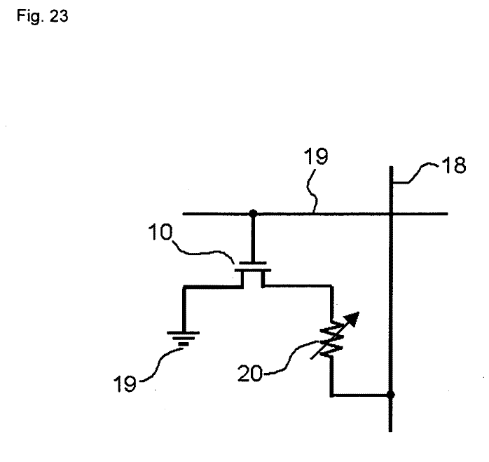

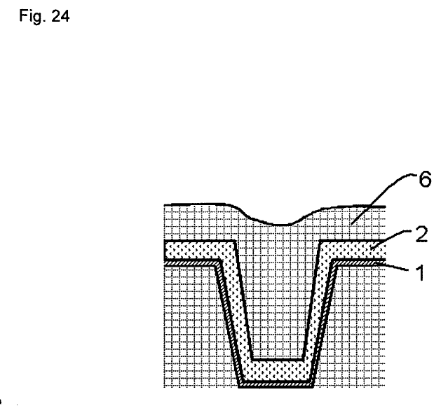

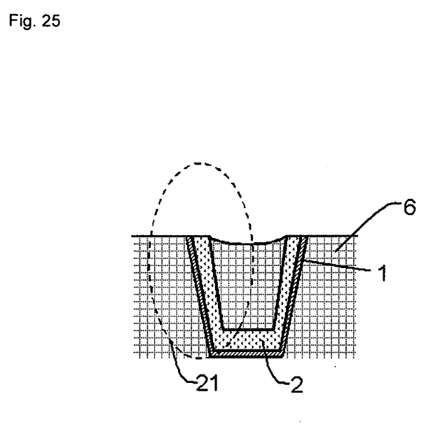

FIG. 3 is a cross section of a phase change memory element with a fine lower electrode. FIGS. 4 to 11 are partial cross sections of each production step for the phase change memory element in relation to a method of producing the phase change memory element in the first embodiment. The method of producing the phase change memory element according to the present embodiment is characterized in that the insulating layer around the lower electrode is formed using the oxidation of silicon to finely form the lower electrode. The phase change memory element is incorporated into the vertical phase change memory device with a configuration illustrated in FIG. 22 to produce a phase change memory device (non-volatile memory device) according to the present invention.

In the present embodiment, although the phase change material is used as the variable change layer, the present invention is not limited to the phase change material.

### (Description of Production Method)

The method of producing the phase change memory element according to the present embodiment is described with reference to FIGS. 4 to 11. The use of a self-alignment technique at the time of producing the phase change memory device can reduce variation in dimension between the elements, suppressing variation in characteristics between the elements in a memory cell array.

FIG. 4 illustrates contact plug 7 and insulating layer 6. Although not illustrated in the figure, contact plug 7 is connected to an active select element such as a transistor (refer to FIG. 22). A method of forming the contact plug is described below. An insulating film of, for example, silicon nitride (Si₃N₄) is deposited on an active select element formed on a silicon substrate or on an underlying substrate such as a silicon substrate and patterned using lithography techniques to form a first opening. In a cell configuration having an active select element, although not illustrated, the first opening is formed so that the phase change memory element is connected to the active select element by contact plug 7. If the cell has a lower wire, the opening is arranged to connect with the lower wire in the circuitry. If the opening is formed by the lithography techniques, the opening is approximately 100 nm in diameter, for example. Next, a material (for example, tungsten (W)) for contact plug 7 is deposited. Thereafter, the surface is planarized by a chemical mechanical polish (CMP) method or an etch back method to form a flat surface of contact plug 7 and insulating layer 6.

As illustrated in FIG. 5, contact plug 7 is subjected to a selective etching to remove a part of contact plug 7 to form second opening 11. In this case, a step between contact plug 7 and insulating layer 6 (or, a depth of second opening 11) may be approximately 25 nm, for example, in consideration of coverage in the opening at the time of depositing an electrode material using the CVD technique or the like. Contact plug 7 may be selectively etched using wet etching or reactive dry etching depending on, for example, a material for the contact plug.

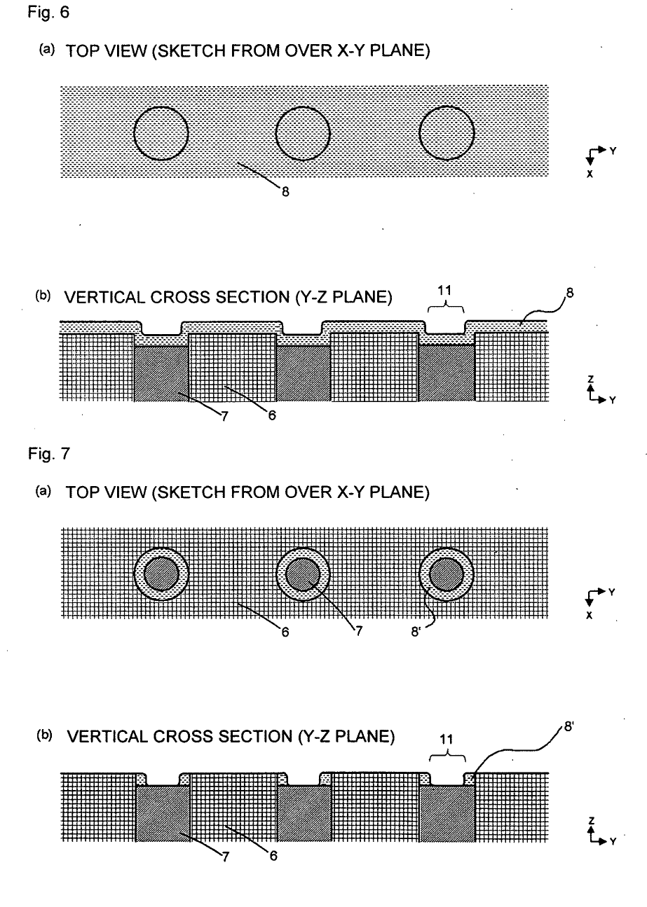

As illustrated in FIG. 6, silicon (si) is deposited approximately 25 nm thick to attain isotropic step coverage so as to form silicon layer 8. Although the shape of the opening in polysilicon is desirably circular or elliptic, it may be polygonal. Although the silicon may be in a crystal state or in an amorphous state, it is preferably polycrystalline in terms of volume increase and crystallinity. Polysilicon is taken in the following description.

As illustrated in FIG. 7, polysilicon layer 8 is subjected to the anisotropic etching process to form side wall 8′ of silicon inside second opening 11 and on contact plug 7. In this case, the cross section of side wall 8′ is preferably formed in a rectangular parallelepiped shape, if possible. The anisotropic etching for polysilicon layer 8 can be accomplished by means of reactive dry etching using mixed gas such as chlorine (Cl₂), hydrogen bromide (HBr) and oxygen (O₂).

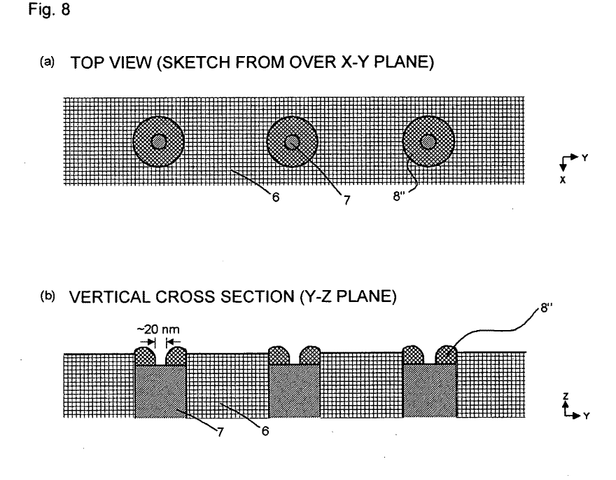

As illustrated in FIG. 8, polysilicon of side wall 8′ is oxidized to reduce the diameter of second opening 11. Specifically, the volume of side wall 8′ formed of polysilicon is increased by oxidation due to introducing oxygen into the crystal, and thereby it is possible to reduce the diameter of the opening. In addition, side wall 8′ can be provided with a function as an insulator by oxidation to silicon dioxide (SiO₂). Side wall 8″ denotes oxidized side wall 8′, which is mainly formed of silicon dioxide. The oxidation process substantially increases the volume of the side wall by a factor of two. As a known method, there is the method directly depositing silicon dioxide or silicon nitride to form a side wall. However, the present method has more accurately volume control of the silicon and provides a better coverage than a directly deposited insulating film, and enables the reduction of the thickness of the deposited film and the diameter of the opening in consideration of expansion due to oxidation. For this reason, a hole having a very small diameter can be formed with high controllability, and variation in characteristics of the elements and decrease in yield can be suppressed. The oxidization of polysilicon here can be accomplished using a known method.I It is desirable to use mixed vapor of water (H₂O) and hydrogen (H₂) and selectively oxidize only polysilicon without oxidizing tungsten, using a technique of controlling a vapor pressure ratio (refer to Japanese Patent Laid-Open No. 10-335652). The use of a polysilicon selective oxidization technique eliminates the need for removing the oxide of contact plug 7. If the selective oxidization technique is not used, it is necessary to remove the oxide on the contact plug exposed by selective etching. If the selective oxidization technique described in Japanese Patent Laid-Open No. 10-335652 is used, it is preferable to sufficiently study conditions under which a polysilicon film is thickened because polysilicon has slow oxidation rate.

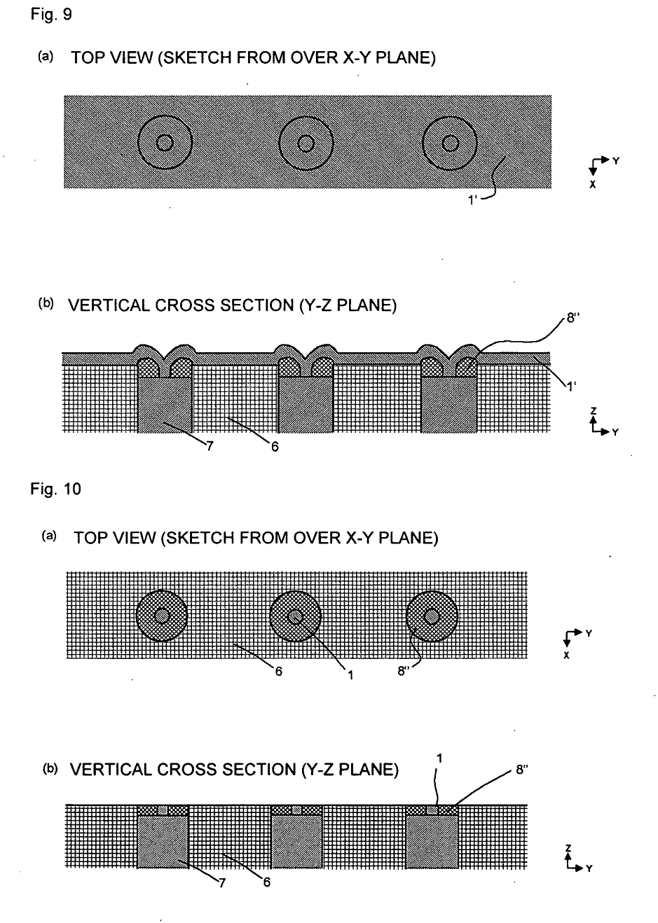

As illustrated in FIG. 9, a lower electrode material such as titanium nitride (TiN) is deposited. As illustrated in FIG. 10, the material is polished and planarized by the CMP method or the etch back method to form lower electrode 1 with a fine cross section.

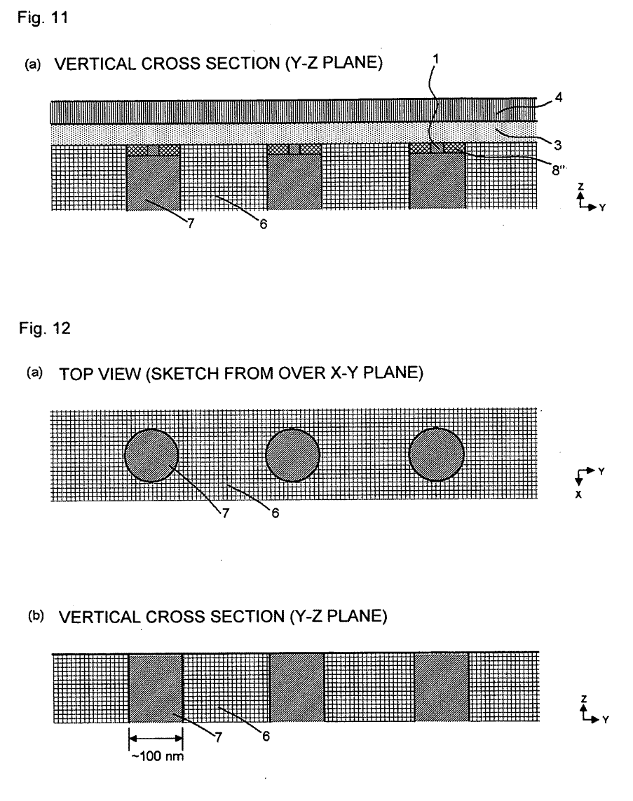

As illustrated in FIG. 11, finally, a vertical phase change memory device can be produced by forming phase change layer 3 made up of a phase change material as a variable resistance material and upper electrode 4 over lower electrode 1. FIG. 11 illustrates one exemplary configuration in which a plurality of the phase change memory elements share upper electrode 4.

### Second Embodiment

FIGS. 12 to 19 show partial cross sections in each production step of the phase change memory element, in relation to a method of producing the phase change memory element according to the second embodiment. In the present invention, polysilicon is oxidized immediately after it is deposited unlike in the first embodiment. With a self-alignment technique also in the present embodiment, variation in dimension between elements can be reduced and variation in characteristics between elements in the memory cell array can be suppressed.

### (Description of Production Method)

A flat surface composed of contact plug 7 and insulating layer 6 is formed in the same method as in the first embodiment (FIG. 12).

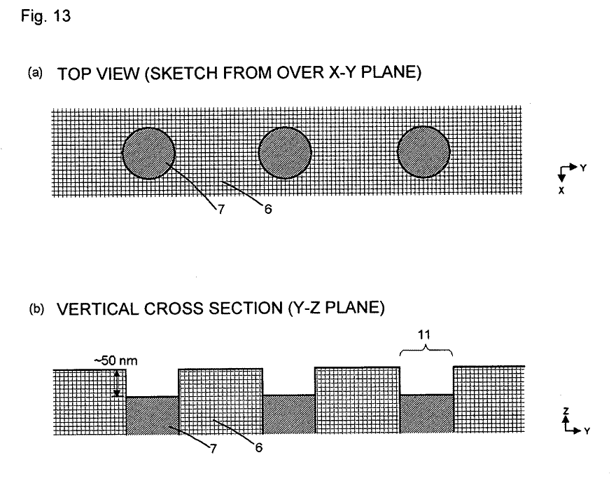

As illustrated in FIG. 13, contact plug 7 is selectively etched to form second opening 11. In the present invention, since silicon is oxidized immediately after it is deposited unlike in the first embodiment, the amount of etch back may increase when a side wall is subsequently formed. Therefore, it may happen that the diameter of the opening unwantedly increase due to the etching. For this reason, it is desirable to etch second opening 11 to approximately 50 nm in depth, which is deeper than in the first embodiment.

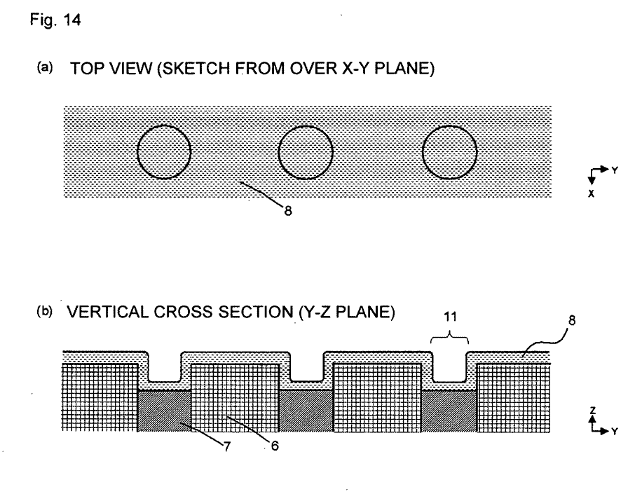

As illustrated in FIG. 14, polysilicon (Si) is deposited to approximately 25 nm thick to attain isotropic step coverage so as to form polysilicon layer 8.

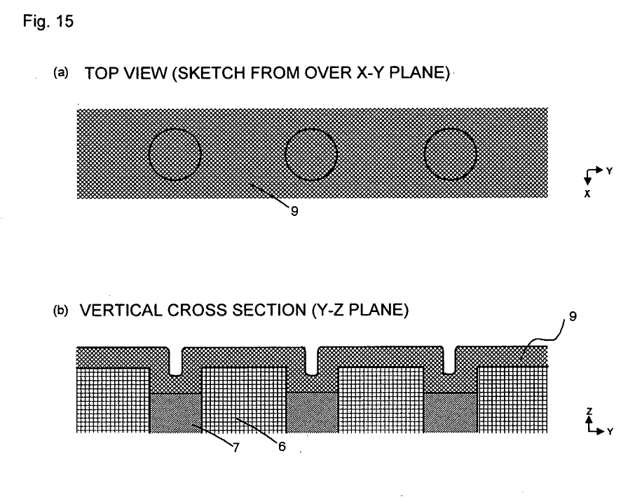

As illustrated in FIG. 15, polysilicon layer 8 is oxidized to silicon dioxide layer 9 to reduce the diameter of the opening. It is preferable to selectively oxidize silicon dioxide layer 9 using the method described in Japanese Patent Laid-Open No. 10-335652. If the selective oxidization technique is not used, tungsten of the contact plug material may be also oxidized and an oxidization layer (or tungsten oxide if tungsten is used) may be formed on the surface of contact plug 7.

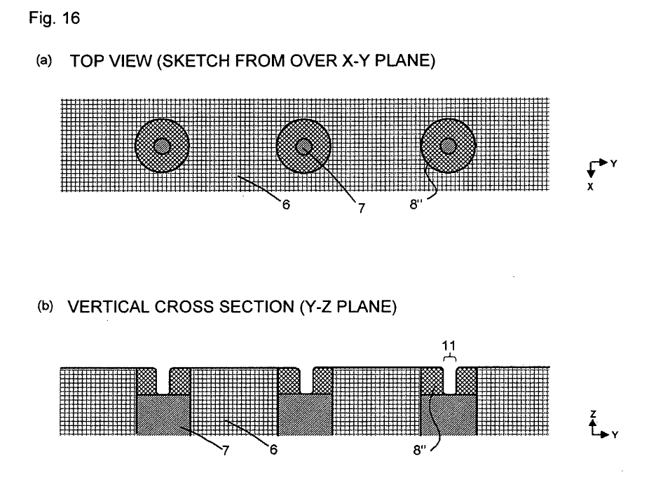

As illustrated in FIG. 16, silicon dioxide layer 9 is subjected to anisotropic etching to remove silicon dioxide layer 9 at the upper center portion of contact plug 7 to form side wall 8″ of silicon dioxide inside second opening 11. It is conceivable to directly deposit silicon dioxide or silicon nitride to form a side wall. The use of the present method, however, can achieve a very small diameter of the opening with high controllability as compared with a directly deposited one, and variation in characteristics of the elements and decrease in yield can be suppressed.

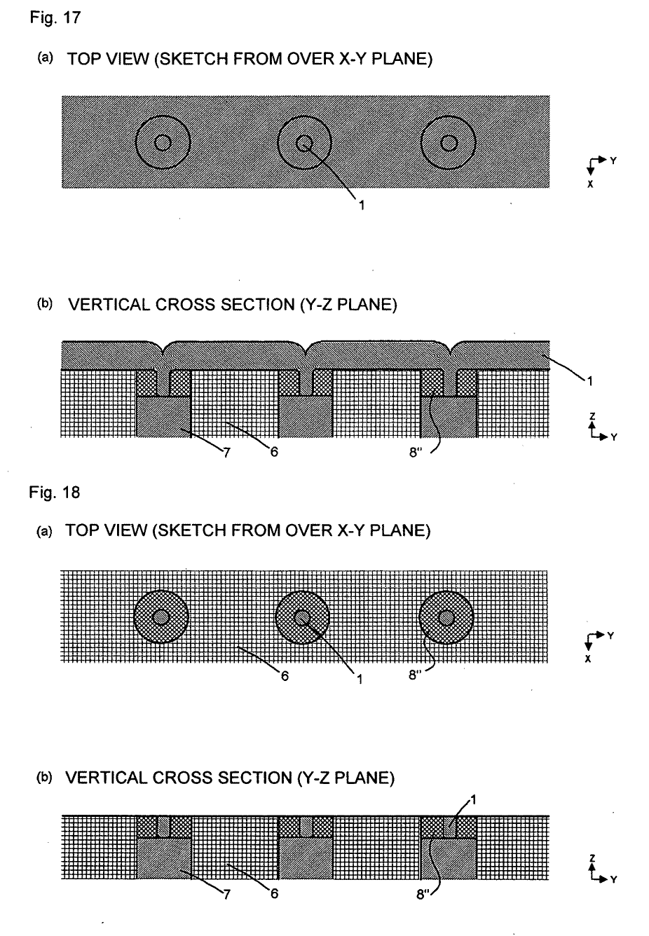

As illustrated in FIG. 17, a lower electrode material such as titanium nitride (TiN) is deposited. As illustrated in FIG. 18, the material is polished and planarized by the CMP method or the etch back method to form lower electrode 1 with a fine cross section.

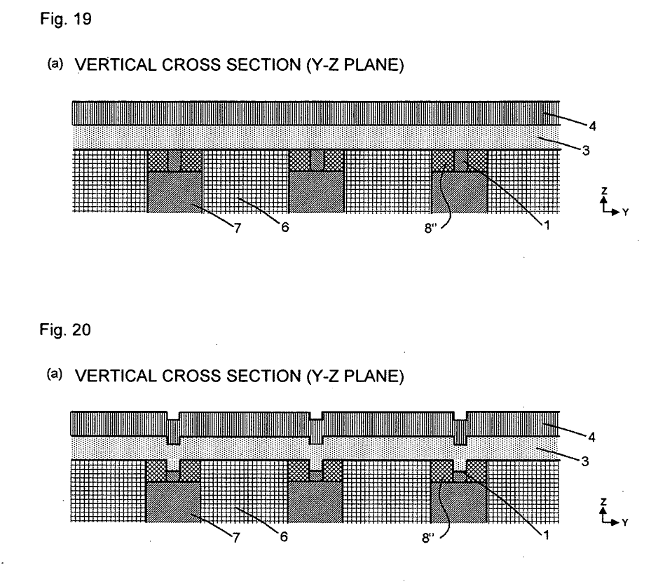

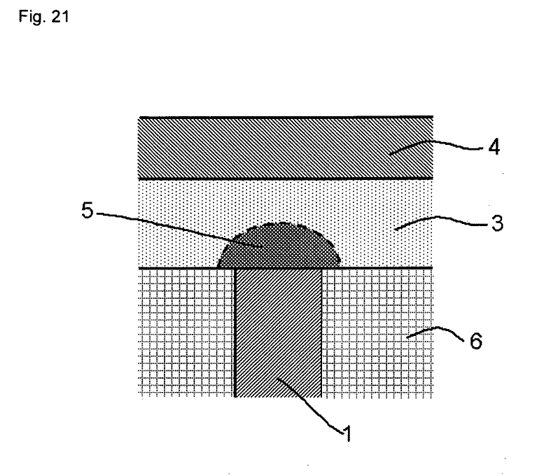

As illustrated in FIG. 19, finally, phase change layer 3 and upper electrode 4 are formed to produce a vertical phase change memory device. FIG. 19 illustrates one exemplary configuration in which a plurality of the phase change memory elements share upper electrode 4.

As illustrated in FIG. 20, lower electrode 1 is formed (after the state in FIG. 18), then, each lower electrode 1 is selectively etched, and thereafter phase change layer 3 and upper electrode 4 may be formed to produce a phase change memory device. In that case, the phase change area is confined to prevent heat from escaping, improving efficiency in the heat generation of the phase change material.

What is claimed is:

1. A method of producing a semiconductor device comprising:
forming a small opening by utilizing cubical expansion due to the oxidation of silicon.

2. The method of producing the semiconductor device according to claim 1, wherein
the small opening is formed by:
depositing the silicon in an opening formed in advance on a substrate; and
reducing a diameter of the opening by oxidizing the silicon.

3. The method of producing the semiconductor device according to claim 2, wherein
the deposited silicon is subjected to an anisotropic etching process before the silicon is oxidized.

4. The method of producing the semiconductor device according to claim 2, wherein
the silicon is oxidized and then subjected to an anisotropic etching process.

5. A method of producing a semiconductor device comprising:
forming an insulating layer on a substrate on which an active select element or a lower wire is formed and forming a first opening connected to the lower wire or the active select element;
depositing a conductive material on the first opening and the insulating layer, and planarizing it to form a contact plug in the first opening;
forming a second opening by selectively etching a part of the contact plug on a flat surface which is formed of the contact plug and the insulating layer;
depositing silicon on the second opening and shaping the silicon by anisotropic etching to form a sidewall comprised of the silicon on a side wall of the second opening;
reducing the diameter of the second opening by selectively oxidizing the sidewall comprised of the silicon to a silicon dioxide (SiO₂);
depositing a material for a lower electrode in the second opening the diameter of which is reduced, and polishing and planarizing the material to form the lower electrode in the second opening; and
forming a variable resistance layer and an upper electrode in this order on the insulating layer including at least on the lower electrode.

6. A method of producing a semiconductor device comprising:
forming an insulating layer on a substrate on which an active select element or a lower wire is formed and forming a first opening connected to the lower wire or the active select element;
depositing a conductive material on the first opening and the insulating layer, and planarizing it to form a contact plug in the first opening;
forming a second opening by selectively etching a part of the contact plug on a flat surface which is formed of the contact plug and the insulating layer;
depositing silicon on the second opening and oxidizing the deposited silicon to reduce the diameter of the second opening;
subjecting the oxidized silicon to an anisotropic etching process to such an extent that the contact plug is exposed;
depositing a material for a lower electrode in the opening the diameter of which is reduced, and polishing and planarizing the material to form a lower electrode; and
forming a variable resistance layer and an upper electrode in this order on the insulating layer including at least on the lower electrode.

7. The method of producing the semiconductor device according to claim 5, wherein
only the silicon is selectively oxidized.

8. The method of producing the semiconductor device according to claim 6, wherein
only the silicon is selectively oxidized.

9. The method of producing the semiconductor device according to claim 5, wherein
the silicon is polycrystal or amorphous silicon.

10. The method of producing the semiconductor device according to claim 6, wherein
the silicon is polycrystal or amorphous silicon.

11. The method of producing the semiconductor device according to claim 5, wherein
in said depositing a material for a lower electrode in the second opening the diameter of which is reduced, and polishing and planarizing the material to form the lower electrode in the second opening, the lower electrode is formed, and then selectively etched so that a part thereof is removed, thereafter said forming a variable resistance layer and an upper electrode in this order is conducted.

12. The method of producing the semiconductor device according to claim 6, wherein
in said depositing a material for a lower electrode in the second opening the diameter of which is reduced, and polishing and planarizing the material to form a lower electrode material in the second opening, the lower electrode is formed and then selectively etched so that a part thereof is removed, thereafter said forming a variable resistance layer and an upper electrode in this order is conducted.

13. The method of producing a variable resistance memory element according to claim 5, wherein
the semiconductor device is a variable resistance memory element.

14. The method of producing a variable resistance memory element according to claim 6, wherein
the semiconductor device is a variable resistance memory element.

15. The method of producing the variable resistance memory element according to claim 5, wherein
the variable resistance layer comprises a phase change material.

16. The method of producing the variable resistance memory element according to claim 6, wherein
the variable resistance layer comprises a phase change material.

17. The method of producing the variable resistance memory element according to claim 15, wherein
the phase change material is chalcogenide.

18. The method of producing the variable resistance memory element according to claim 16, wherein
the phase change material is chalcogenide.

19. A variable resistance memory device comprising the variable resistance memory element produced by the method according to claim 13.

20. A variable resistance memory device comprising the variable resistance memory element produced by the method according to claim 14.
